(19) United States
(12) Patent Application Publication
(10) Pub. No.: US 2026/0322002 A1
(43) Pub. Date: Oct. 15, 2026

(54) CIRCUIT-BOARD CONNECTION STRUCTURE AND LIQUID-LEVEL SENSING DEVICE

(71) Applicant: FINETEK CO., LTD., NEW TAIPEI CITY (TW)

(72) Inventors: Ting-Kuo WU, NEW TAIPEI CITY (TW); Chih-Wen WANG, NEW TAIPEI CITY (TW); Cheng-Tao LI, NEW TAIPEI CITY (TW); Shu-Tien CHANG, NEW TAIPEI CITY (TW)

(21) Appl. No.: 19/249,253

(22) Filed: Jun. 25, 2025

(30) Foreign Application Priority Data
Apr. 11, 2025 (TW) 114203609

(51) Int. Cl. H01R 12/52; G01F 23/22; H05K 1/14

(52) U.S. Cl. CPC H01R 12/523; G01F 23/22; H05K 1/142

(57) ABSTRACT

A circuit-board connection structure and a liquid-level sensing device are provided. The circuit-board connection structure includes two printed circuit boards (PCBs) and at least one conductive connector. The two PCBs are arranged close to each other, each including a first surface with a printed circuit and a second surface opposite the first surface. The conductive connector includes a connection body and a plurality of pins disposed on the connection body. The connection body spans the first surfaces of the two PCBs, and the pins are positioned on the first surfaces and electrically connected to the printed circuits.

### BACKGROUND OF THE DISCLOSURE

### Technical Field

The present disclosure relates to flexible circuit boards, and more particularly to a circuit‑board connection structure and a liquid‑level sensing device that employs the structure.

### Description of Related Art

Related-art printed circuit boards (PCBs) are limited in length during production by factors such as material properties and manufacturing‑equipment capacity, so they are typically fabricated in lengths of no more than one meter. For applications requiring longer lengths, two PCBs are often joined using circular holes and riveted with small connecting plates. However, this method becomes cumbersome for lengths of six to ten meters, leading to complex processing procedures. The electrical connection relies on the combination of the PCB, connecting plates, and circular holes, which compromises the stability of the product during processing. Additionally, the junction between the PCB and the connecting plates becomes rigid, making it prone to poor contact when the assembly is coiled or bent.

In liquid‑level sensor applications, a waterproof outer tube is required to protect the circuitry. When the length is excessive, the assembly must be coiled for transport and on‑site installation. Because the riveted joints may loosen during handling, poor contact or increased impedance can occur, preventing accurate measurement. In industrial applications, this may cause control errors and, ultimately, safety incidents such as liquid overflow.

To overcome these shortcomings, the inventor carried out extensive research and applied theoretical principles to develop the present design, which effectively addresses the issues described above.

### SUMMARY OF THE DISCLOSURE

A primary object of the present disclosure is to provide a circuit-board connection structure and a liquid-level sensing device that utilize a conductive metal connector to join two printed circuit boards (PCBs). The conductive metal connector is thinner than the PCBs and is flexible, making it suitable for bending after the PCBs are joined and allowing the width at the joint to be reduced.

Another object of the present disclosure is to provide a circuit-board connection structure and a liquid-level sensing device that incorporate a dual-layer protection design, including protective accessories on the back surfaces of the joined PCBs.

To achieve the above objects, the present disclosure provides a circuit-board connection structure, including two printed circuit boards and at least one conductive connector. The two printed circuit boards are positioned adjacent to each other, each of the printed circuit boards having a first surface and a second surface opposite to the first surface, wherein the first surface is provided with a printed circuit. The conductive connector includes a connection body and a plurality of pins extending from the connection body, wherein the connection body straddles the first surfaces of the two printed circuit boards, and the pins of the conductive connector are positioned on the first surfaces and electrically connected to the printed circuits.

To achieve the above objects, the present disclosure also provides a liquid-level sensing device including an outer tube, an outer tube fixing member connected to one end of the outer tube, a hanging member connected to another end of the outer tube, and the aforementioned circuit-board connection structure. The circuit-board connection structure is disposed within the outer tube and electrically connected to a sensing module.

### BRIEF DESCRIPTION OF THE DRAWINGS

FIG. 1 is a partial perspective view of the circuit-board connection structure according to an embodiment of the present disclosure.

FIG. 2 is an enlarged detailed view of portion A of FIG. 1.

FIG. 3 is a partial exploded perspective view of the circuit-board connection structure according to an embodiment of the present disclosure.

FIG. 4 is a plan view of portion A of FIG. 1.

FIG. 5 is a cross-sectional view taken along line 5-5 of FIG. 4.

FIG. 6 is a perspective view of portion A of FIG. 1 from another angle.

FIG. 7 is a cross-sectional view of another embodiment according to FIG. 5.

FIG. 8 is a perspective schematic view of the liquid-level sensing device according to an embodiment of the present disclosure.

### DETAILED DESCRIPTION

To further disclose the features and technical content of the present disclosure, reference is made to the following detailed description and accompanying drawings. The drawings are provided for reference and illustration purposes only and are not intended to limit the scope of the disclosure.

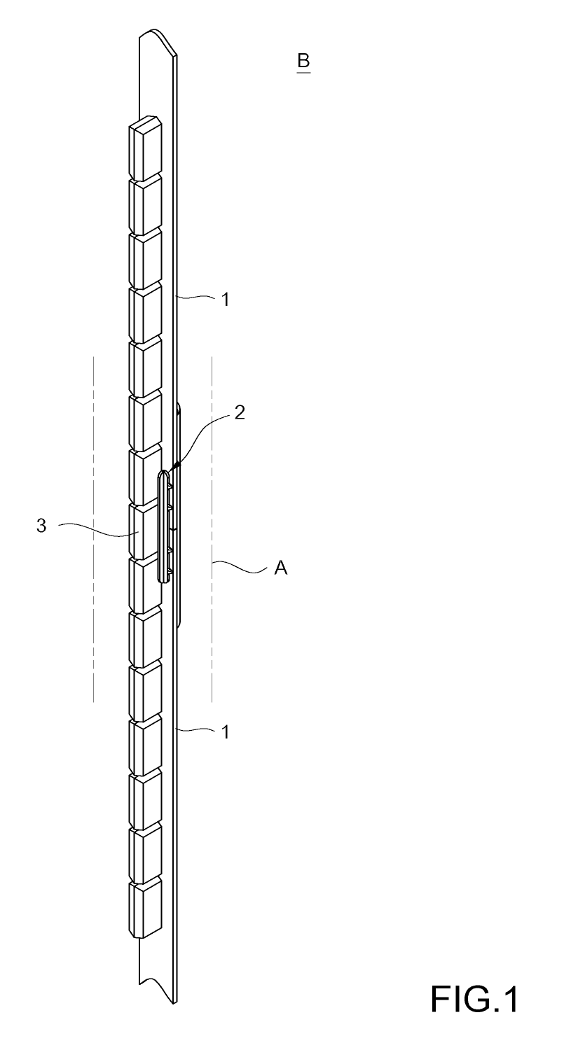

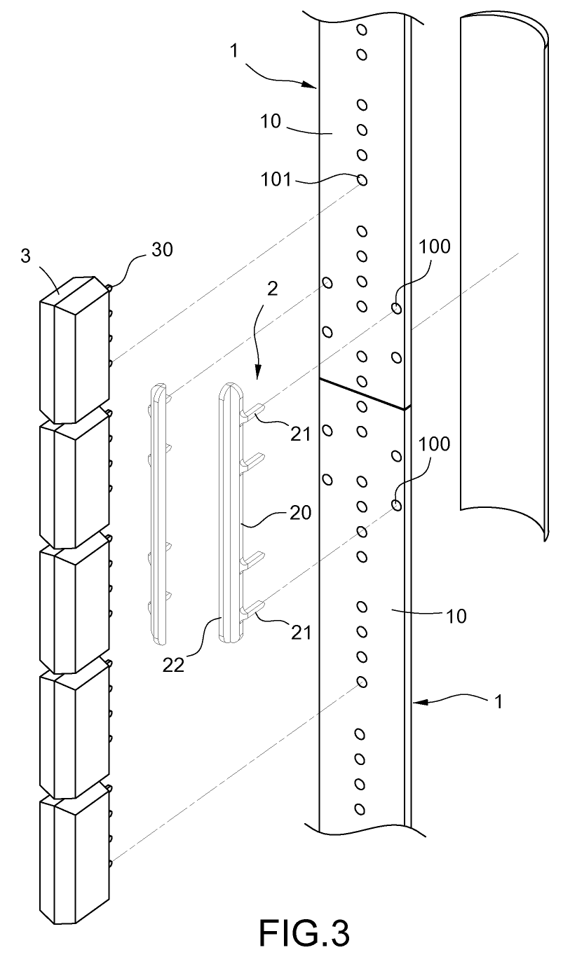

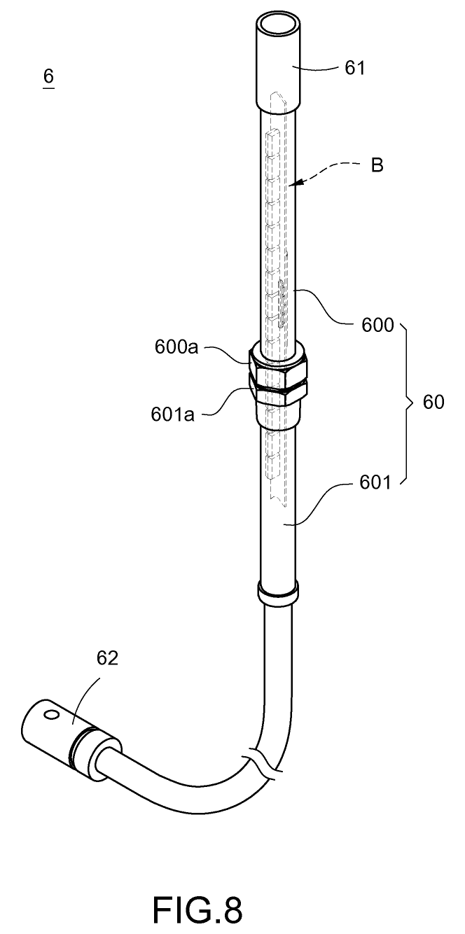

Referring to FIGS. 1 and 3, which are a partial perspective view and a partial exploded perspective view of the circuit-board connection structure, respectively, the present disclosure provides a circuit-board connection structure and a liquid-level sensing device. The circuit-board connection structure B is suitable for use in a liquid-level sensing device 6 (as shown in FIG. 8) and includes two printed circuit boards (PCBs) 1 and at least one conductive connector 2.

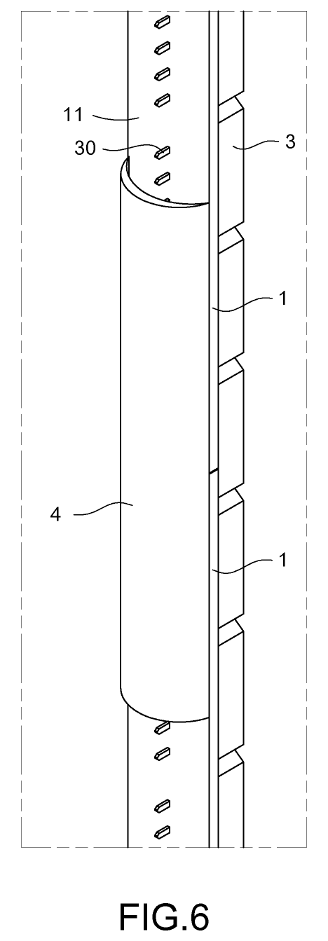

Each of the two PCBs 1 may be elongated and have an appropriate length, which may be determined based on actual requirements or constrained by the maximum length achievable in the manufacturing process. As shown in FIGS. 3 and 6, the two PCBs 1 are positioned close to each other. Each PCB 1 has a first surface 10 and a second surface 11 opposite the first surface 10. The first surface 10 is provided with a printed circuit (not shown in figures) for electrically connecting a plurality of electronic components 3 mounted thereon via soldering. The second surface 11 may be covered with a protective cover 4, which spans (straddles) the two PCBs 1. The protective cover 4 may be made of plastic or an insulating material.

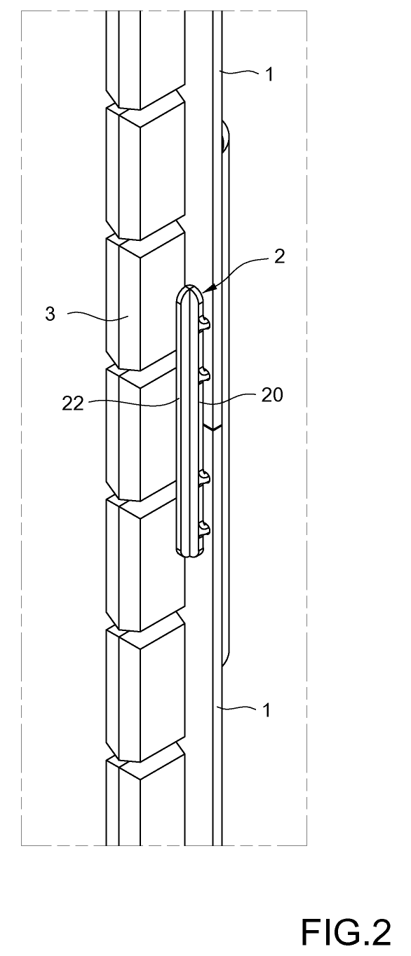

As shown in FIGS. 2 and 3, the conductive connector 2 is made of a conductive metal material. Each conductive connector 2 includes an elongated connection body 20 and a plurality of pins 21 extending from the connection body 20. The connection body 20 spans across the first surfaces 10 of the two PCBs 1, allowing the pins 21 to be soldered to the printed circuits (not shown in figures) on the first surfaces 10 of the two PCBs 1, thereby electrically connecting the two PCBs 1 through the conductive connector 2. Specifically, each PCB 1 includes a plurality of pin guiding holes 100 and component guiding holes 101 on its first surface 10. The pins 21 of the conductive connector 2 correspond to the pin guiding holes 100, while pins 30 of the electronic components 3 correspond to the component guiding holes 101. The printed circuit (not shown in figures) extends to the pin guiding holes 100 and the component guiding holes 101, enabling electrical connectivity between the two PCBs 1.

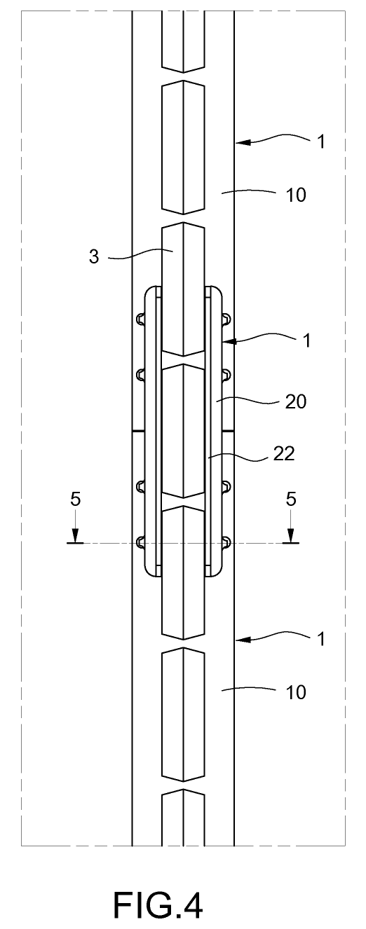

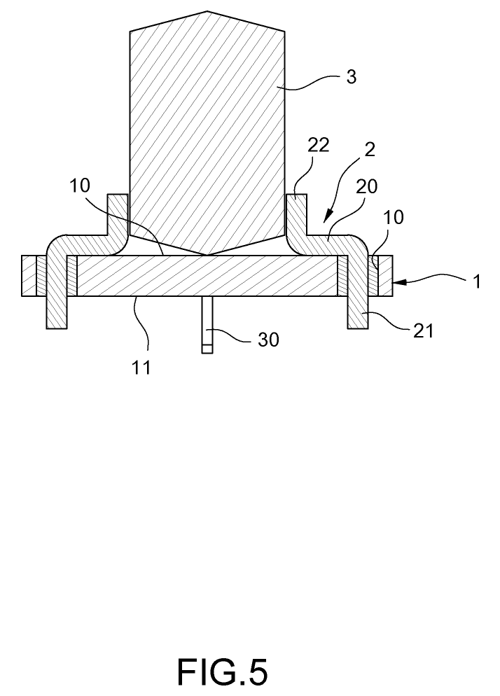

Furthermore, as shown in FIGS. 4 and 5, the number of conductive connectors 2 may be two, respectively positioned on two sides of any one of the electronic component 3. Each connection body 20 of the conductive connectors 2 includes an abutment edge 22 extending along the length direction of the connection body 20. The abutment edge 22 abuts against one side of any one of the electronic component 3, thereby positioning the electronic component 3 between the two conductive connectors 2 and preventing the electronic component 3, which spans between the two PCBs 1, from tilting due to bending or impact.

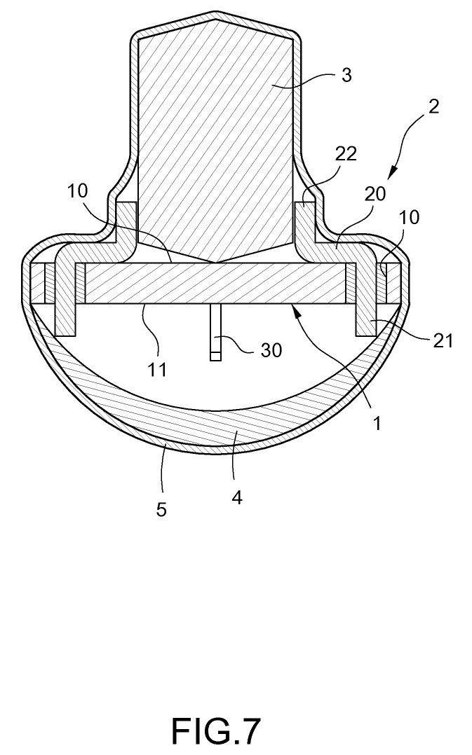

Additionally, as shown in FIG. 7, the circuit board connection structure B may further include a sleeve 5 that encases the protective cover 4 and the corresponding electronic component 3. The sleeve 5 may be a standard sleeve or a heat-shrinkable tube and may provide functionalities such as corrosion resistance, acid and alkali resistance, and waterproofing.

As shown in FIG. 8, the circuit-board connection structure B may be applied to a liquid-level sensing device 6. The liquid-level sensing device 6 may be an elongated, suspended type. The liquid-level sensing device 6 includes an outer tube 60, an outer tube fixing member 61 connected to one end of the outer tube 60, and a hanging member 62 connected to the other end of the outer tube 60. The outer tube 60 comprises a protective hose 600 and a flexible hose 601. The protective hose 600 includes a first connector 600a, and the flexible hose 601 includes a second connector 601a. The protective hose 600 and the flexible hose 601 are connected to and communicate with each other via the first connector 600a and the second connector 601a, allowing the circuit-board connection structure B to be disposed within the outer tube 60 and electrically connected to a sensing module (not shown in figures). This configuration enables the circuit-board connection structure B to be used in electronic products requiring bending, particularly in elongated, suspended liquid-level sensing devices 6.

Thus, through the circuit-board connection structure and the liquid-level sensing device of the present disclosure, the circuit-board connection structure B utilizes conductive connectors 2 made of metal to join two printed circuit boards (PCBs) 1. The conductive connectors 2 are thinner and more flexible than the PCBs 1. The connectors 2 may be directly processed to form the pins 21 which are inserted into pin guiding holes 100 of the mating PCBs 1 for soldering, thereby serving as both a mechanical connector and an electrical conductor between the two PCBs 1. This allows the connection width between the PCBs 1 to be reduced, while providing a rapid, robust connection with improved flexibility and strength. The structure effectively prevents issues such as loosening or poor conductivity caused by bending or twisting of the PCBs 1. Additionally, the incorporation of the protective cover 4 and the sleeve 5 achieves a dual-layer protective design.

Therefore, through the aforementioned structural configuration, the circuit-board connection structure and liquid-level sensing device of the present disclosure are realized.

The above description covers example embodiments of the present disclosure and does not limit its patent scope. Equivalent structural modifications made based on the specification and drawings, or direct/indirect applications in other related technical fields, are included within the patent protection scope of the present disclosure.

What is claimed is:

1. A circuit-board connection structure, comprising:
two printed circuit boards, positioned adjacent to each other, each of the printed circuit boards comprising a first surface and a second surface opposite to the first surface, wherein a printed circuit is disposed on the first surface; and
at least one conductive connector, comprising a connection body and a plurality of pins disposed on the connection body, wherein the connection body straddles multiple first surfaces of the two printed circuit boards, and the pins of the conductive connector are disposed on the first surfaces and electrically connected to the printed circuits.

2. The circuit-board connection structure according to claim 1, wherein the two printed circuit boards are both an elongated shape.

3. The circuit-board connection structure according to claim 1, wherein a plurality of electronic components are disposed on the first surfaces of the two printed circuit boards and electrically connected to the printed circuits.

4. The circuit-board connection structure according to claim 3, wherein each printed circuit board comprises a plurality of pin guiding holes and a plurality of component guiding holes defined on the first surface, the pins of the conductive connector are respectively corresponding to the pin guiding holes, and a plurality of pins of the electronic components are respectively corresponding to the component guiding holes.

5. The circuit-board connection structure according to claim 3, wherein two conductive connectors are respectively positioned on two sides of any one of the electronic components, the connection body of each conductive connector comprises an abutment edge extending along a length direction of the connection body, and the abutment edge abuts against one side of any one of the electronic components.

6. The circuit-board connection structure according to claim 3, wherein multiple second surfaces of the two printed circuit boards are covered with a protective cover.

7. The circuit-board connection structure according to claim 6, further comprising a sleeve encasing the protective cover and corresponding one of the electronic components.

8. The circuit-board connection structure according to claim 1, wherein the conductive connector is made of a metal material.

9. A liquid-level sensing device, comprising:
an outer tube, comprising a protective hose and a flexible hose connected to and communicating with each other;
an outer tube fixing member, connected to one end of the outer tube;
a hanging member, connected to another end of the outer tube; and
a circuit-board connection structure of claim 1, disposed within the outer tube and electrically connected to a sensing module.

10. The liquid-level sensing device according to claim 9, wherein the liquid-level sensing device is an elongated shape and suspended.

11. The liquid-level sensing device according to claim 9, wherein the two printed circuit boards are both an elongated shape.

12. The liquid-level sensing device according to claim 9, wherein a plurality of electronic components are disposed on the first surfaces of the two printed circuit boards and electrically connected to the printed circuits.

13. The liquid-level sensing device according to claim 12, wherein each printed circuit board comprises a plurality of pin guiding holes and a plurality of component guiding holes defined on the first surface, the pins of the conductive connector are respectively corresponding to the pin guiding holes, and a plurality of pins of the electronic components are respectively corresponding to the component guiding holes.

14. The liquid-level sensing device according to claim 12, wherein two conductive connectors are respectively positioned on two sides of any one of the electronic components, the connection body of each conductive connector comprises an abutment edge extending along a length direction of the connection body, multiple abutment edge abuts against one side of any one of the electronic components.

15. The liquid-level sensing device according to claim 12, wherein the second surfaces of the two printed circuit boards are covered with a protective cover.

16. The liquid-level sensing device according to claim 15, further comprising a sleeve encasing the protective cover and corresponding one of the electronic components.

17. The liquid-level sensing device according to claim 9, wherein the conductive connector is made of a metal material.
